(19) United States
(12) Patent Application Publication
(10) Pub. No.: US 2006/0256979 A1
(43) Pub. Date: Nov. 16, 2006

(54) Array speaker system

(75) Inventors: Akira Usui, Hamamatsu-shi (JP); Masao Noro, Hamamatsu-shi (JP)

Correspondence Address: ROSSI, KIMMS & McDOWELL LLP., P.O. BOX 826, ASHBURN, VA, 20146-0826, US

(73) Assignee: Yamaha Corporation, Hamamatsu-shi (JP)

(21) Appl. No.: 10/555,907

(22) PCT Filed: May 6, 2004
(86) PCT No.: PCT/JP04/06423

§ 371 Date: Nov. 7, 2005

(30) Foreign Application Priority Data
May 9, 2003 (JP) 2003-131538

(51) Int. Cl. H03G 5/00

(52) U.S. Cl. 381/98

(57) ABSTRACT

An array speaker system is constituted by a plurality of speaker units, which are equipped with weighting means respectively and to which weight coefficients based on a Bessel function are imparted. An input signal is transmitted through an all-pass filter whose phase rotates by 180° in high-frequency ranges and is then supplied to those of the speaker units whose weight coefficients have negative values. Thus, a signal of an inverse phase is output with respect to low-frequency ranges; hence, it is possible to avoid the deterioration of audio emission characteristics, and it is possible to avoid the occurrence of beams and comb shapes in audio emission characteristics with respect to signals of high-frequency ranges.

### TECHNICAL FIELD

This invention relates to array speaker systems in which a plurality of speaker units are arrayed in a one-dimensional manner or a two-dimensional manner.

### BACKGROUND ART

Conventionally, array speaker systems in which a plurality of speakers are regularly arranged so as to reproduce and output sounds are known. In these array speaker systems, as a form of trouble due to the use of plural speakers, there occurs a phenomenon in which as reproduced audio frequencies become higher, so-called beams and comb shapes (i.e., sounds are spread in a comb-shape manner) emerge in audio emission characteristics, which vary in response to frequencies and which make it difficult to realize audition of high-frequency sound outside of an audio emission center position, or in which frequency characteristics greatly vary in response to listening positions.

FIGS. 13A to 13E show simulation results regarding audio emission characteristics when fifteen speaker units are vertically and linearly disposed with 2.5 cm distances therebetween so that they each emit sound of the same phase. That is, FIGS. 13A to 13E show audio emission characteristics measured in horizontal cross-sectional planes and vertical cross-sectional planes when audio frequencies of 500 Hz, 1000 Hz, 10 kHz, and 15 kHz are generated with prescribed speaker setup positions as well as audio emission characteristics (i.e., sound pressure distribution) in a projection plane that is 2 m distant from the front surface of the speaker system. Herein, they show that sound pressure becomes higher in white areas compared with black areas.

As shown in the aforementioned drawings, beams and comb shapes apparently occur in audio emission characteristics with respect to audio frequencies of several kilo Hz or higher.

In order to avoid the occurrence of this phenomenon, a Bessel array method in which by imparting weights using a string of coefficients based on a first-order Bessel function to a string of regularly arranged speakers, audio emission characteristics are made to be spherical is known. For example, Japanese Examined Patent Application Publication No. HO 1-25480 discloses a simplified Bessel array.

FIG. 14 is a circuit diagram showing essential parts of an array speaker system adopting a Bessel array. The array speaker system shown in FIG. 14 has fifteen speaker units, wherein reference numerals 11-1 to 11-15 designate fifteen speaker units that are linearly disposed with a prescribed distance d (e.g., d=2.5 cm) therebetween; and reference numerals 12-1 to 12-15 designate weighting means for imparting weight coefficients C1 to C15 to signals respectively supplied to the corresponding speaker units 11-1 to 11-15. Normally, power amplifiers are inserted between the weighting means 12-1 to 12-15 and the corresponding speaker units 11-1 to 11-15, but the present specification omits the illustration thereof. As the weighting means 12-1 to 12-15, it is possible to use amplifiers having gains corresponding to weight coefficients.

Herein, the weight coefficients C1 to C15 are each calculated based on the first-order Bessel function that is defined by the following equation.

$${J}_{n} ( x ) = {( \frac{x}{2} )}^{n} {\sum }_{k = 0}^{∞} \frac{{( - 1 )}^{k} {( x / 2 )}^{2 k}}{k ! Γ ( n + k + 1 )}$$

In this example in which fifteen speaker units are used, values of J₋₇(x) to J₇(x) according to the aforementioned equation are used. When x=6.0, it is possible to produce weight coefficients C1 to C15 imparted to the fifteen speakers as follows:
C1=J₋₇(6)=−0.1296
C2=J₋₆(6)=0.2458
C3=J₋₅(6)=−0.3621
C4=J₋₄(6)=0.3576
C5=J₋₃(6)=−0.1148
C6=J₋₂(6)=−0.2429
C7=J₋₁(6)=0.2767
C8=J₀(6)=0.1506
C9=J₁(6)=−0.2767
C10=J₂(6)=−0.2429
C11=J₃(6)=0.1148
C12=J₄(6)=0.3576
C13=J₅(6)=0.3621
C14=J₆(6)=0.2458
C15=J₇(6)=0.1296

FIGS. 15A to 15E show simulation results regarding audio emission characteristics measured when the speaker units 11-1 to 11-15, to which weight coefficients C1 to C15 based on the first-order Bessel function are imparted, are driven, wherein they show audio emission characteristics measured in horizontal cross-sectional planes and vertical cross-sectional planes when audio frequencies of 500 Hz, 1000 Hz, 5000 Hz, 10 kHz, and 15 kHz are generated with prescribed speaker setup positions as well as audio emission characteristics in a projection plane that is 2 m distant from the front surface of the speaker system.

Compared with FIGS. 13A to 13E, FIGS. 15A to 15E show that no beams and no comb shapes occur in audio emission characteristics in the Bessel array; hence, it is possible to realize the aforementioned spherical audio emission characteristics. As described above, driving the speaker units using the weight coefficients based on the Bessel function is an effective measure for avoiding the occurrence of beams and comb shapes in audio emission characteristics.

However, as the weight coefficients C1 to C15 based on the Bessel function include negative values, audio emission characteristics in low frequency ranges may deteriorate; therefore, it is difficult to reproduce low-frequency sound. In particular, such a phenomenon brings a bad result in array speaker systems in which plural speaker units are installed in common enclosures or common enclosures of the bass-reflex type.

In consideration of the aforementioned circumstances, it is an object of the present invention to provide an array speaker system in which in a broad range of frequencies ranging from low frequencies to high frequencies, it is possible to avoid the occurrence of beams and comb shapes in audio emission characteristics and to efficiently realize audio emission.

### DISCLOSURE OF THE INVENTION

An array speaker system of this invention is constituted by arraying a plurality of speaker units, wherein all speaker units are driven with the same phase in response to signals of low-frequency ranges, while the speaker units are separately driven with weight coefficients based on a Bessel function in response to signals of high-frequency ranges.

Alternatively, it is possible to drive all speaker units with the same phase and with the same gain in response to-signals of low-frequency ranges.

In addition, all-pass filters that are set up to realize phase rotation of 180° in high-frequency ranges are arranged, so that speaker units whose weight coefficients based on the Bessel function have negative values are driven with absolute values of weight coefficients, which are imparted to signals supplied thereto by way of the all-pass filters, while other speaker units whose weight coefficients based on the Bessel function do not have negative values are directly driven with the weight coefficients thereof without the intervention of the all-pass filters.

Furthermore, in an array speaker system of this invention, there are provided all-pass filters that are set up to realize phase rotation of 180° in high-frequency ranges, means that are respectively connected to speaker units whose weight coefficients based on the Bessel function have negative values so as to impart gain characteristics corresponding to absolute values of weight coefficients to signal components of high-frequency ranges within signals input thereto by way of the all-pass filters, and means that are respectively connected to speaker units whose weight coefficients based on the Bessel function do not have negative values so as to impart gain characteristics corresponding to weight coefficients to signal components of high-frequency ranges.

The aforementioned all-pass filters can be set up in such a way that the phase rotation thereof is set to 90° with respect to frequencies in proximity to frequencies corresponding to wavelengths corresponding to widths of speaker units.

Furthermore, in an array speaker system of this invention, there are provided filter means for dividing input signals into signal components of low-frequency ranges and signal components of high-frequency ranges, weighting means that are respectively connected to speaker units so as to impart weight coefficients based on the Bessel function to signal components of high-frequency ranges, and addition means that are respectively connected to speaker units so as to add signal components of low-frequency ranges to signal components of high-frequency ranges, to which weight coefficients based on the Bessel function are imparted by the weighting means, thus outputting addition results to the speaker units.

Incidentally, in the array speaker system of this invention, a plurality of speaker units are installed in a common enclosure or a common enclosure of a bass-reflex type, for example.

### BRIEF DESCRIPTION OF THE DRAWINGS

FIG. 1 is a circuit diagram showing essential parts of an array speaker system in accordance with a first embodiment of this invention;

FIG. 2A shows an example of the constitution of an all-pass filter shown in FIG. 1;

FIG. 2B shows phase characteristics of the all-pass filter;

FIG. 3A shows audio emission characteristics measured upon generation of an audio frequency of 500 Hz in the array speaker system of the first embodiment;

FIG. 3B shows audio emission characteristics measured upon generation of an audio frequency of 1000 Hz in the array speaker system of the first embodiment;

FIG. 3C shows audio emission characteristics measured upon generation of an audio frequency of 5000 Hz in the array speaker system of the first embodiment;

FIG. 3D shows audio emission characteristics measured upon generation of an audio frequency of 10 kHz in the array speaker system of the first embodiment;

FIG. 3E shows audio emission characteristics measured upon generation of an audio frequency of 15 kHz in the array speaker system of the first embodiment;

FIG. 4A shows an example of the constitution of an IIR digital all-pass filter;

FIG. 4B shows phase characteristics of the IIR digital all-pass filter;

FIG. 5 is a circuit diagram showing essential parts of an array speaker system in accordance with a second embodiment of this invention;

FIG. 6A shows an example of the constitution of an amplifier connected to a prescribed speaker unit;

FIG. 6B shows an example of the constitution of a high-pass filter of a shelving type, which is connected to a prescribed speaker unit;

FIG. 6C shows an example of the constitution of a high-cut filter of a shelving type, which is connected to a prescribed speaker unit;

FIG. 7 show gain characteristics of circuits that are constituted as shown in FIGS. 6A to 6C;

FIG. 8A shows an example of a circuit constitution of a filter connected to each speaker unit in an array speaker system in accordance with a third embodiment of this invention;

FIG. 8B shows gain characteristics of the filter shown in FIG. 8A;

FIG. 8C shows phase characteristics of the filter shown in FIG. 8A;

FIG. 9A shows another example of the circuit constitution of the aforementioned filter;

FIG. 9B shows gain characteristics of the filter shown in FIG. 9A;

FIG. 9C shows phase characteristics of the filter shown in FIG. 9A;

FIG. 10 is a circuit diagram showing essential parts of the array speaker system in accordance with the third embodiment of this invention;

FIG. 11A shows audio emission characteristics measured upon generation of an audio frequency of 900 Hz when the gain of each speaker unit is set to “1”;

FIG. 11B shows audio emission characteristics measured upon generation of an audio frequency of 1000 Hz when the gain of each speaker unit is set to “1”;

FIG. 11C shows audio emission characteristics measured upon generation of an audio frequency of 1200 Hz when the gain of each speaker unit is set to “1”;

FIG. 11D shows audio emission characteristics measured upon generation of an audio frequency of 1500 Hz when the gain of each speaker unit is set to “1”;

FIG. 12 is a circuit diagram showing essential parts of an array speaker system in accordance with a fourth embodiment of this invention;

FIG. 13A shows audio emission characteristics measured upon generation of an audio frequency of 500 Hz in the conventional array speaker system;

FIG. 13B shows audio emission characteristics measured upon generation of an audio frequency of 1000 Hz in the conventional array speaker system;

FIG. 13C shows audio emission characteristics measured upon generation of an audio frequency of 5000 Hz in the conventional array speaker system;

FIG. 13D shows audio emission characteristics measured upon generation of an audio frequency of 10 kHz in the conventional array speaker system;

FIG. 13E shows audio emission characteristics measured upon generation of an audio frequency of 15 kHz in the conventional array speaker system;

FIG. 14 is a circuit diagram showing essential parts of an array speaker system adopting a Bessel array;

FIG. 15A shows audio emission characteristics measured upon generation of an audio frequency of 500 Hz in the array speaker system adopting the Bessel array;

FIG. 15B shows audio emission characteristics measured upon generation of an audio frequency of 1000 Hz in the array speaker system adopting the Bessel array;

FIG. 15C shows audio emission characteristics measured upon generation of an audio frequency of 5000 Hz in the array speaker system adopting the Bessel array;

FIG. 15D shows audio emission characteristics measured upon generation of an audio frequency of 10 kHz in the array speaker system adopting the Bessel array; and

FIG. 15E shows audio emission characteristics measured upon generation of an audio frequency of 15 kHz in the array speaker system adopting the Bessel array.

### BEST MODE FOR CARRYING OUT THE INVENTION

Preferred embodiments of this invention will be described in detail with reference to the accompanying drawings.

First, a description will be given with respect to the basic principle of an array speaker system of this invention.

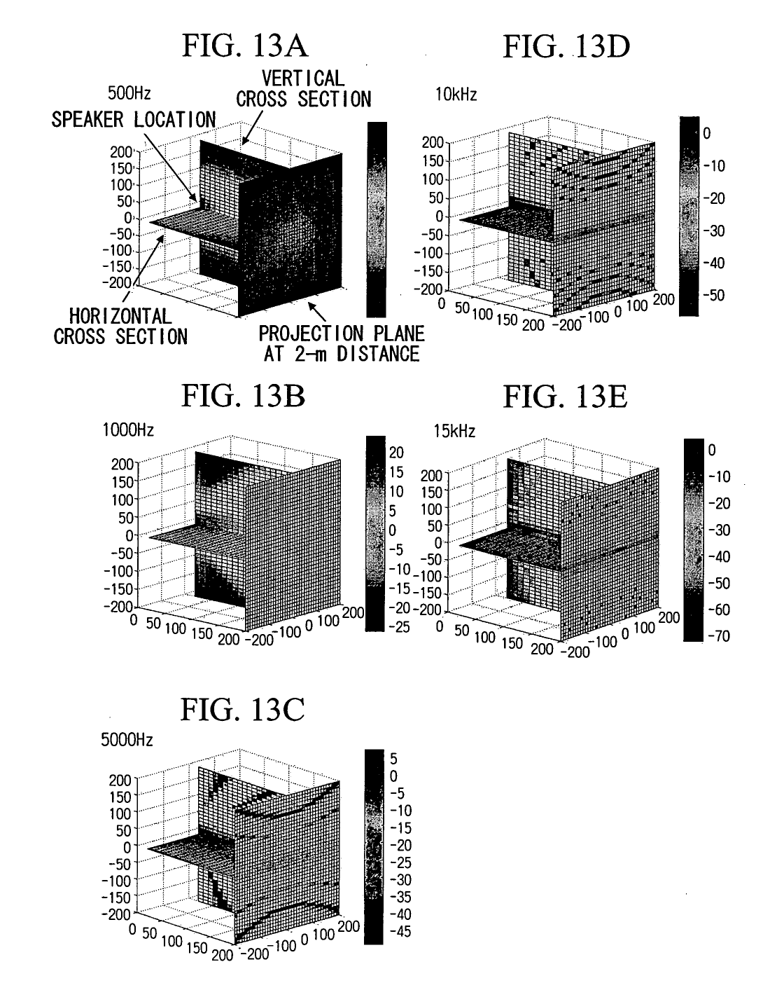

As shown in audio emission characteristics shown in FIGS. 13A to 13E, when all speaker units forming the array speaker system emit sounds of prescribed audio frequencies with the same phase, no beams and no comb shapes occur in audio emission characteristics in low-frequency ranges (i.e., frequencies of 1 kHz or lower shown FIGS. 13A and 13B) even when weighting is not effected using weight coefficients based on the Bessel function. For this reason, this invention is designed such that in low-frequency ranges causing no problem due to beams and comb shapes in audio emission characteristics, the speaker units are each driven with the positive phase so as to prevent audio emission characteristics from deteriorating, while in high-frequency ranges causing beams and comb shapes in audio emission characteristics, the speaker units are each driven with weight coefficients based on the Bessel function. Thus, in a broad range of frequencies ranging from low-frequency ranges to high-frequency ranges, it is possible to efficiently perform sound emission while avoiding the occurrence of beams and comb shapes in audio emission frequencies.

Hereinafter, a description will be given with respect to an array speaker system of this invention in which speaker units are each driven with the positive phase in low-frequency ranges and are each driven with weight coefficients based on the Bessel function in high-frequency ranges.

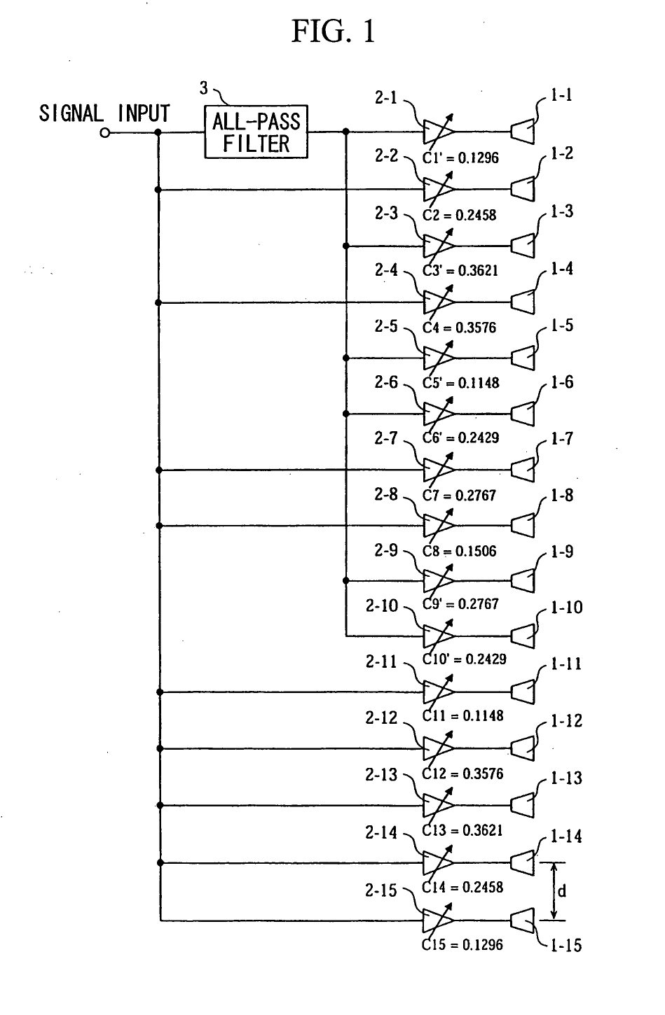

FIG. 1 is a circuit diagram showing essential parts of an array speaker system in accordance with a first embodiment of this invention. In the present embodiment similarly to in the conventional example, the array speaker system is formed using fifteen speaker units, wherein weight coefficients based on the Bessel function are set similar to the foregoing values of C1 to C15. However, this invention is not necessarily limited to the aforementioned constitution; hence, this invention can be similarly applied to other array speaker systems each having plural speaker units (e.g., five speaker units or more), wherein weight coefficients can be set to prescribed values other than the foregoing values of C1 to C15.

In addition, the present embodiment is designed such that speaker units are each driven with the positive phase in low-frequency ranges and are each driven with weight coefficients based on the Bessel function in high-frequency ranges. For this reason, the present embodiment uses all-pass filters whose phases vary by 180° in high-frequency ranges.

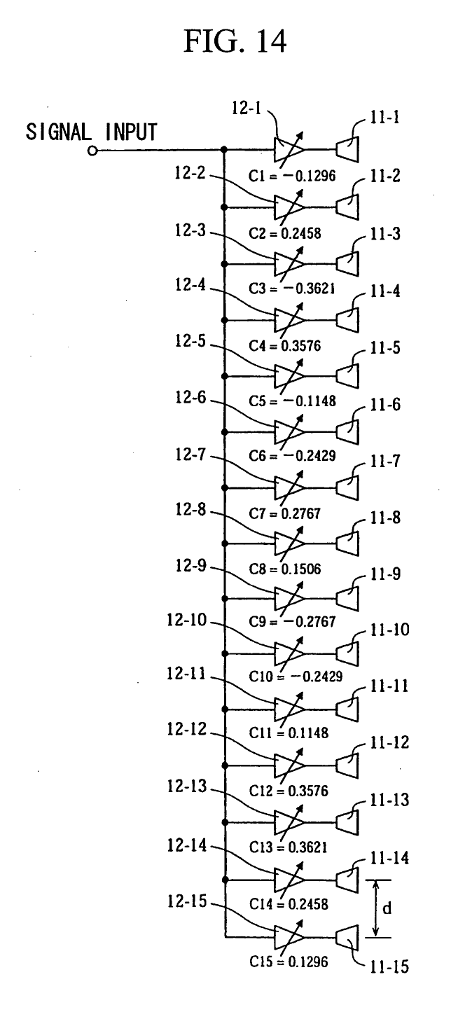

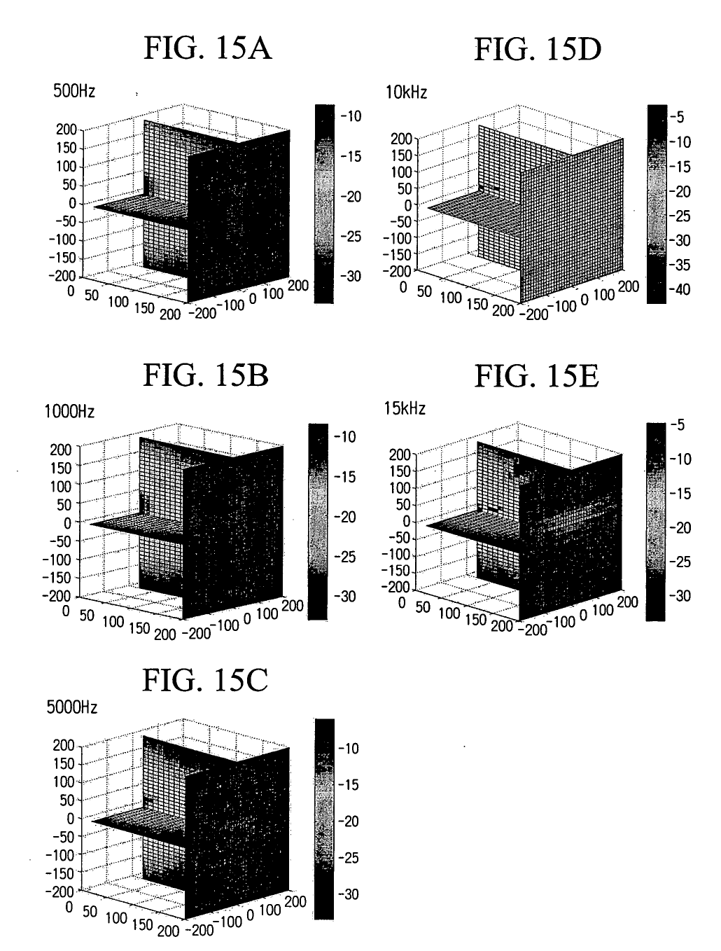

In FIG. 1, reference numerals 1-1 to 1-15 designate fifteen speaker units that are disposed with a prescribed distance d (e.g., d=2.5 cm) therebetween; and reference numerals 2-1 to 2-15 designate weighting means for weighting signals, which are supplied to the corresponding speaker units 1-1 to 1-15, by use of weight coefficients based on the Bessel function. They correspond to ones designated by reference numerals 11-1 to 11-15 and reference numerals 12-1 to 12-15 shown in FIG. 14. However, FIG. 1 differs from FIG. 14 in that weight coefficients adopted in the weighting means 2-1 to 2-15 are given as absolute values. That is, in the array speaker system shown in FIG. 14, negative values are set to the weight coefficients C1, C3, C5, C6, C9, and C10, whereas in the array speaker system shown in FIG. 1, the weighting means 2-1, 2-3, 2-5, 2-6, 2-9, and 2-10 adopt weight coefficients C1′, C3′, C5′, C6′, C9′, and C10′ represented by absolute values.

A reference numeral 3 designates an all-pass filter whose amplitude characteristics are flat over all frequency ranges and whose phase characteristics realize phase rotation of 0° in low-frequency ranges but are reversed by way of variation of 180° in high-frequency ranges.

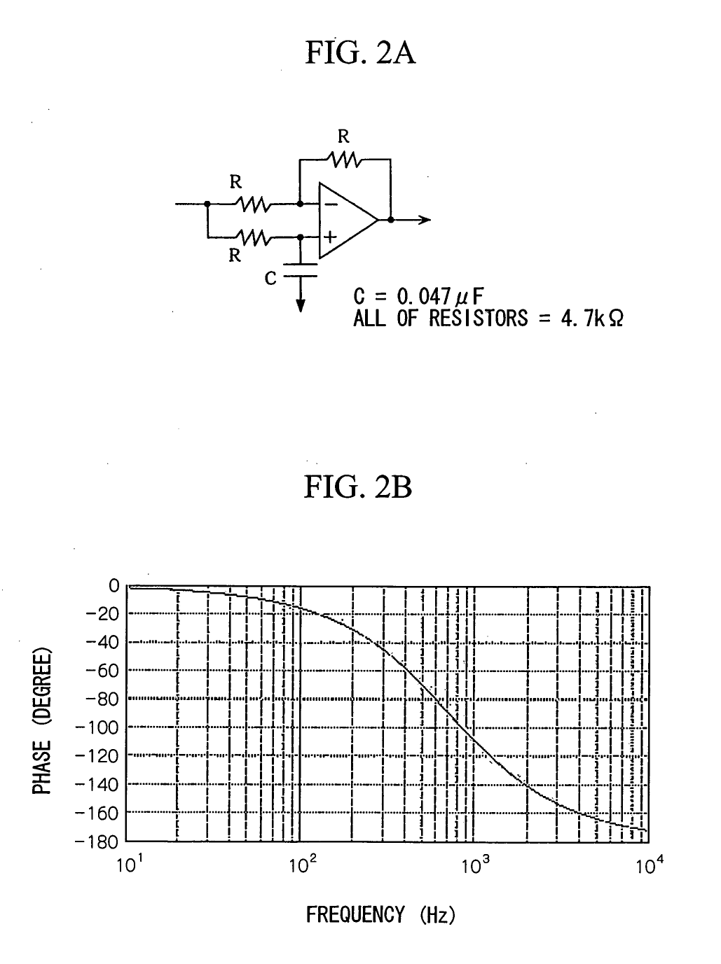

FIG. 2A shows an example of the constitution of the all-pass filter; and FIG. 2B shows phase characteristics thereof. As shown in FIG. 2B, the all-pass filter 3 has phase characteristics in which the phase rotation is set to 0° in low-frequency ranges, it is gradually increased as frequency becomes higher, it reaches 90° at approximately 700 Hz, and it is set to 180° in high-frequency ranges that are 10 kHz or above.

In FIG. 1, an input signal applied to a signal input terminal is directly supplied to the weighting means 2-2, 2-4, 2-7, 2-8, 2-11, 2-12, 2-13, 2-14, and 2-15 whose weight coefficients based on the Bessel function have positive values, while it is supplied to the other weighting means 2-1, 2-3, 2-5, 2-6, 2-9, and 2-10 by way of the all-pass filter 3. The input signal being supplied as described above is given individual weight coefficients in the weighting means 2-1 to 2-15, outputs of which are then supplied to the speaker units 1-1 to 1-15 respectively.

That is, signals to which weight coefficients are applied in the corresponding weighting means are respectively supplied to the speaker units 1-2, 1-4, 1-7, 1-8, and 1-11 to 1-15 whose weight coefficients based on the Bessel function have positive values. In addition, weighting having the same phase (i.e., the same polarity) as the weighting applied to the speaker units whose weight coefficients based on the Bessel function have positive values is applied to the speaker units 1-1, 1-3, 1-5, 1-6, 1-9, and 1-10 whose weight coefficients based on the Bessel function have negative values with respect to low-frequency signals on which the all-pass filter 3 effects phase rotation not exceeding 90°. In contrast, with respect to high-frequency signals on which the all-pass filter 3 effects phase rotation exceeding 90°, weighting having the reverse phase (i.e., the reverse polarity) as the weighting applied to the speaker units whose weight coefficients based on the Bessel function have positive values is applied to them.

That is, in high-frequency ranges, negative weight coefficients are applied to the speaker units whose weight coefficients based on the Bessel function have negative values, thus making the weight coefficients based on the Bessel function operate effectively. In low-frequency ranges, signals having the same phase are supplied to the corresponding speaker units; therefore, it is possible to reproduce low-frequency sound with a sufficient amplitude.

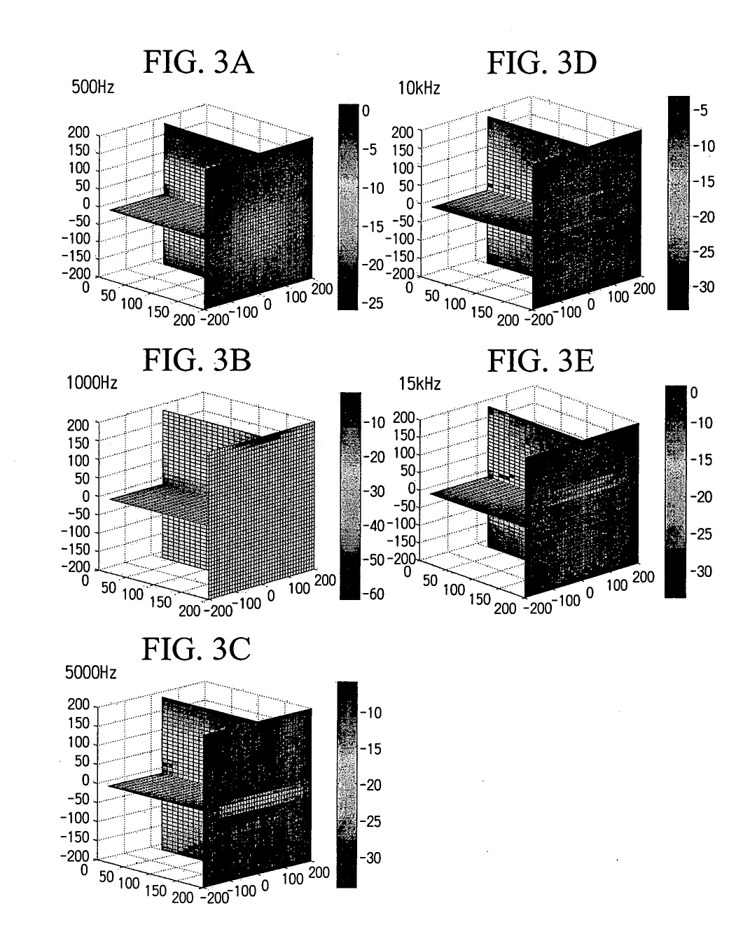

FIGS. 3A to 3E show simulation results of audio emission characteristics in the present embodiment, and show audio emission characteristics measured in horizontal cross-sectional planes and vertical cross-sectional planes when audio frequencies of 500 Hz, 1000 Hz, 5000 Hz, 10 kHz, and 15 kHz are generated with prescribed speaker setup positions as well as audio emission characteristics in the projection plane that is 2 m distant from the front surface of the speaker system.

Compared with the foregoing audio emission characteristics shown in FIGS. 13A to 13E, as shown in FIGS. 3A to 3E, it is possible to adequately avoid the occurrence of beams and comb shapes in audio emission characteristics in the present embodiment.

Incidentally, the all-pass filter 3 is not necessarily formed using an analog filter as shown in FIG. 2A; hence, it can be formed using a digital filter equipped with an A/D converter and a D/A converter before and after it.

For instance, suppose that the analog all-pass filter 3 shown in FIG. 2A has a transfer function as follows:

$$H ( S ) = \frac{1 - CRS}{1 + CRS}$$

It is subjected to bilinear transform in a Z-axis region by use of the following formula.

$$S = \frac{2}{T * \frac{( 1 - {Z}^{- 1} )}{1 + {Z}^{- 1}}}$$

Hence, it is transformed as follows:

$$H ( Z ) = \frac{( T - 2 CR ) + ( T + 2 CR ) {Z}^{- 1}}{( T + 2 CR ) + ( T - 2 CR ) {Z}^{- 1}}$$

In the above, when C=0.047 μF, R=4.7 kΩ, and sampling frequency fs=48 Hz, it is represented as follows:

$$H ( Z ) = \frac{- 420 * {10}^{- 1} + ( 460 * {10}^{- 1} ) {Z}^{- 1}}{460 * {10}^{- 1} + ( - 420 * {10}^{- 1} ) {Z}^{- 1}}$$

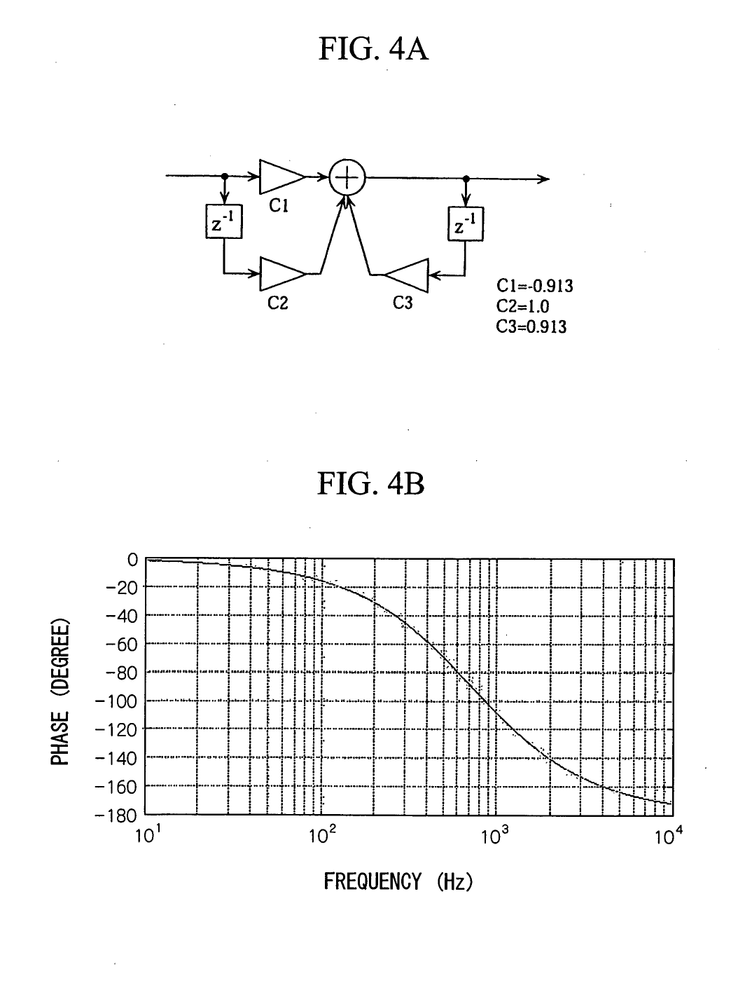

This digital filter can be formed using an IIR (Infinite Impulse Response) filter shown in FIG. 4A, which has the phase characteristics shown in FIG. 4B.

As described above, the speaker units each have different weight coefficients based on the Bessel function. For example, in the case of the weight coefficients C1 to C15 shown in FIG. 14, C3=−0.3621 whose absolute value is maximal is increased in gain approximately 3.15 times more than C5=−0.1148 whose absolute value is minimal. For this reason, audio conversion efficiency in low-frequency ranges, which do not need weighting using weight coefficients based on the Bessel function, must be reduced.

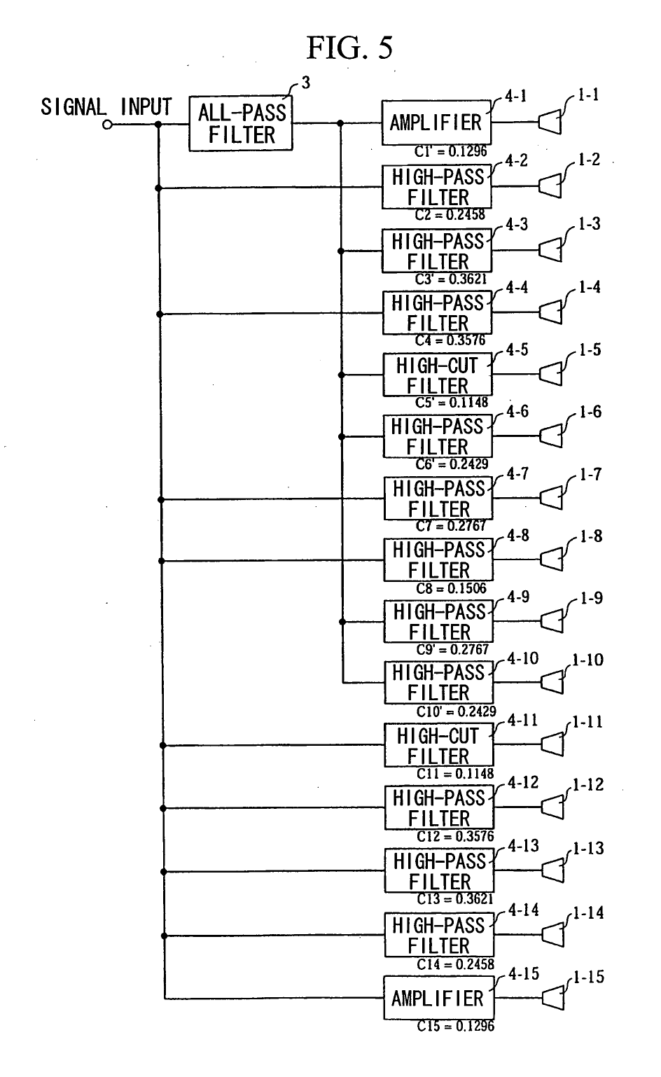

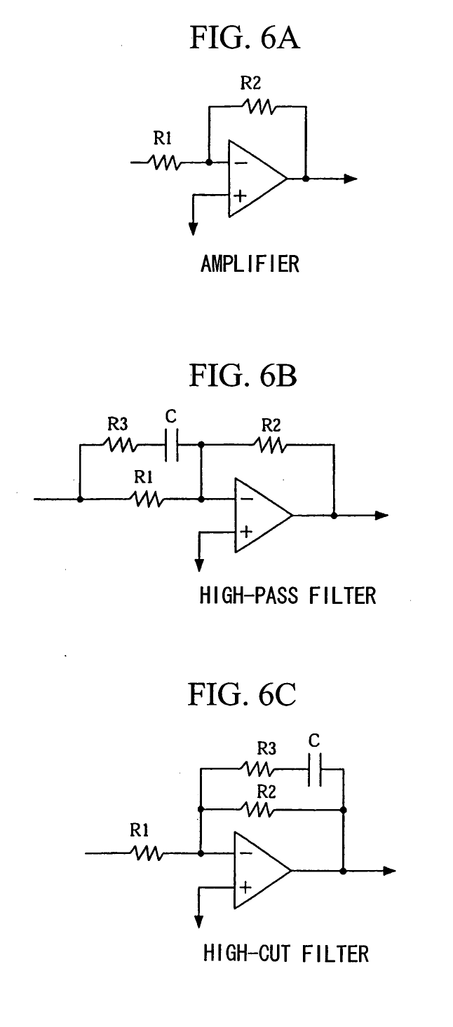

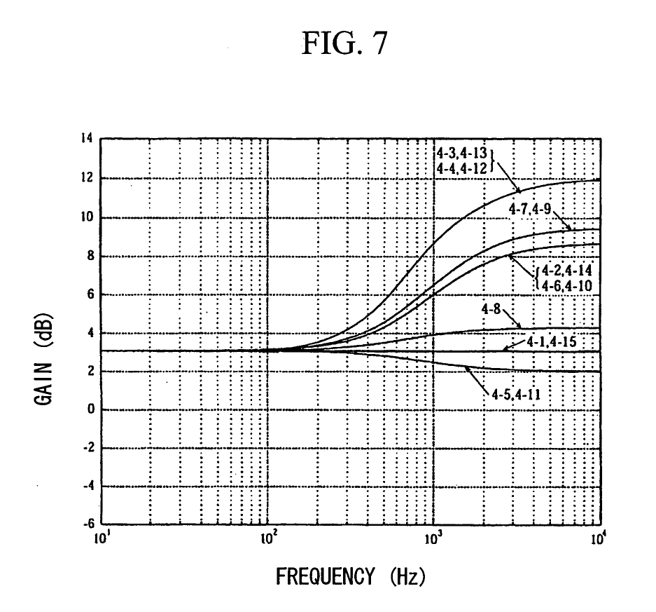

A second embodiment of this invention, which is designed to eliminate the aforementioned drawback, will be described with reference to FIG. 5, FIGS. 6A to 6C, and FIG. 7.

In the second embodiment, filters that have the same gain with respect to low-frequency ranges and that have gains in response to weight coefficients based on the Bessel function with respect to high-frequency ranges are used as weighting means. That is, a reference speaker unit is set up; then, flat gain characteristics are applied to the reference speaker unit. For the other speaker units, the same gain as the gain of the reference speaker unit is set with respect to low-frequency ranges; and filters having gain characteristics, which represent ratios of weight coefficients of the other speaker units, compared with the weight coefficient of the reference speaker unit, are used as weighting means with respect to high-frequency ranges. Incidentally, similarly to in the aforementioned first embodiment, the output of the all-pass filter 3 is directly supplied to the speaker units whose weight coefficients based on the Bessel function have negative values.

In FIG. 5, reference numerals 1-1 to 1-15 designate speaker units; reference numeral 3 designates an all-pass filter; and reference numerals 4-1 to 4-15 designate circuits for imparting prescribed weights to speaker units 1-1 to 1-15. In the second embodiment, the speaker unit 1-1 (weight coefficient C1′=0.1296) is used as the reference speaker unit. Because of the relationship regarding weight coefficients C15=C1′, the speaker unit 1-15 corresponds to the reference speaker unit. Therefore, amplifiers 4-1 and 4-15 having flat frequency characteristics are connected to the reference speaker units 1-1 and 1-15 respectively.

As absolute values of weight coefficients applied to the speaker units 1-2 to 1-4, 1-6 to 1-10, and 1-12 to 1-14 are greater than the absolute value 0.1296 of the weight coefficient applied to the reference speaker unit, high-pass filters 4-2 to 4-4, 4-6 to 4-10, and 4-12 to 4-14, each of which is a so-called shelving type, are connected to them. These high-pass filters have flat gain characteristics in low-frequency ranges; and they also have gain characteristics that are increased in response to ratios of the weight coefficients applied to the corresponding speaker units compared with the reference weight coefficient C1 (C15) with respect to high-frequency ranges.

Both of the weight coefficients applied to the other speaker units 1-5 and 1-11 are set to 0.1148, which is lower than the reference weight coefficient 0.1296. Hence, high-cut filters of the shelving type that have flat gain characteristics in low-frequency ranges and that also have gain characteristics, which are decreased in response to ratios of the weight coefficients thereof compared with the reference weight coefficient C1, are connected to them.

FIG. 6A shows an example of the constitution adapted to the aforementioned amplifiers 4-1 and 4-15. FIG. 6B shows an example of the constitution adapted to the aforementioned high-pass filters 4-2 to 4-4, 4-6 to 4-10, and 4-12 to 4-14. Furthermore, FIG. 6C shows an example of the constitution adapted to the aforementioned high-cut filters 4-5 and 4-11.

In the circuits shown in FIGS. 6A to 6C, a dc gain (i.e., a gain in low-frequency ranges) is determined by a ratio (R2/R1) between resistors R2 and R1. In addition, the same values of the resistors R1 and R2 are used in the circuits designated by reference numerals 4-1 to 4-15. Therefore, the same gain is applied to signals supplied to the speaker units 1-1 to 1-15 with respect to low-frequency ranges. Specifically, the setup is made such that R1=33 kΩ and R2=47 kΩ; therefore, the dc gain is set to 20 log(47/33)=3.07 dB.

In each of the high-pass filter and high-cut filter shown in FIGS. 6B and 6C, prescribed values are selected for a resistor R3 and a capacitor C respectively in order for the gain in high-frequency ranges to be set in response to the ratio of the absolute value of the corresponding weight coefficient compared with the reference weight coefficient (0.1296).

For example, with respect to the high-pass filter 4-2 having the weight coefficient C2=0.2458, circuit constants thereof (i.e., R3=36 kΩ, C=3300 pF) are determined in order for the gain thereof in high-frequency ranges to be increased by 20 log(0.2458/0.1296)=5.56 dB compared with the gain of the amplifier 4-1 connected to the reference speaker unit 1-1, i.e., it is set to 3.07+5.56=8.63 dB. With respect to the high-pass filter 4-3, circuit constants thereof (i.e., R3=18 kΩ, C=5600 pF) are determined in order for the gain thereof in high-frequency ranges to be set to 20 log(0.3621/0.1296)+3.07=12.0 dB. Similarly, with respect to the high-pass filter 4-4, the gain thereof is set to 20 log(0.3576/0.1296)+3.07=11.9 dB, which is approximately identical to the gain of the high-pass filter 4-3; hence, circuit constants thereof (i.e., R3=18 kΩ, C=5600 pF) are similarly set up. Based on similar calculations, circuit constants of R3=36 kΩ and C=3300 pF are set with respect to the high-pass filter 4-6; circuit constants of R3=30 kΩ and C=3900 pF are set with respect to the high-pass filter 4-7; circuit constants of R3=20 kΩ and C=1000 pF are set with respect to the high-pass filter 4-8; circuit constants of R3=30 kΩ and C=3900 pF are set with respect to the high-pass filter 4-9; circuit constants of R3=36 kΩ and C=3300 pF are set with respect to the high-pass filter 4-10; circuit constants of R3=18 kΩ and C=5600 pF are set with respect to the high-pass filter 4-12; circuit constants of R3=18 kΩ and C=5600pF are set with respect to the high-pass filter 4-13; and circuit constants of R3=36 kΩ and C=3300 pF are set with respect to the high-pass filter 4-14.

Furthermore, both of the high-cut filters 4-5 and 4-11 have the same weight coefficient whose absolute value is 0.1148; hence, circuit constants thereof (i.e., R3=360 kΩ, C=470 pF) are determined as shown in FIG. 6C in order for the gain thereof in high-frequency ranges to have a difference of 20 log(0.1148/10.1296)=−1.05 dB compared with the gain of the amplifier 4-1 connected to the reference speaker unit, i.e., it is set to 3.07−1.05=2.02 dB.

FIG. 7 shows gain characteristics of the aforementioned circuits designated by reference numerals 4-1 to 4-15. As shown in FIG. 7, the circuits each have the same gain and flat characteristics in low-frequency ranges, whereas the gains thereof in high-frequency ranges are varied in response the corresponding weight coefficient.

As described above, in the second embodiment, in low-frequency ranges at which no problem occurs with regard to beams and comb shapes in audio emission characteristics, signals having the same phase and the same gain are supplied to the speaker units, wherein as frequencies become higher, signals given weights based on the Bessel function are supplied to them. Therefore, in the present embodiment, it is possible to prevent the audio emission efficiency in the low-frequency sound from being reduced; and it is possible to avoid the occurrence of beams and comb shapes in audio emission characteristics.

Incidentally, in the aforementioned embodiment, the speaker unit 1-1 is selected as the reference speaker unit, but this invention is not necessarily limited by the aforementioned embodiment; hence, it is possible to arbitrarily select a desired speaker unit as the reference speaker unit. In addition, it is possible to form the aforementioned high-pass filters and high-cut filters by use of digital filters, instead of analog filters.

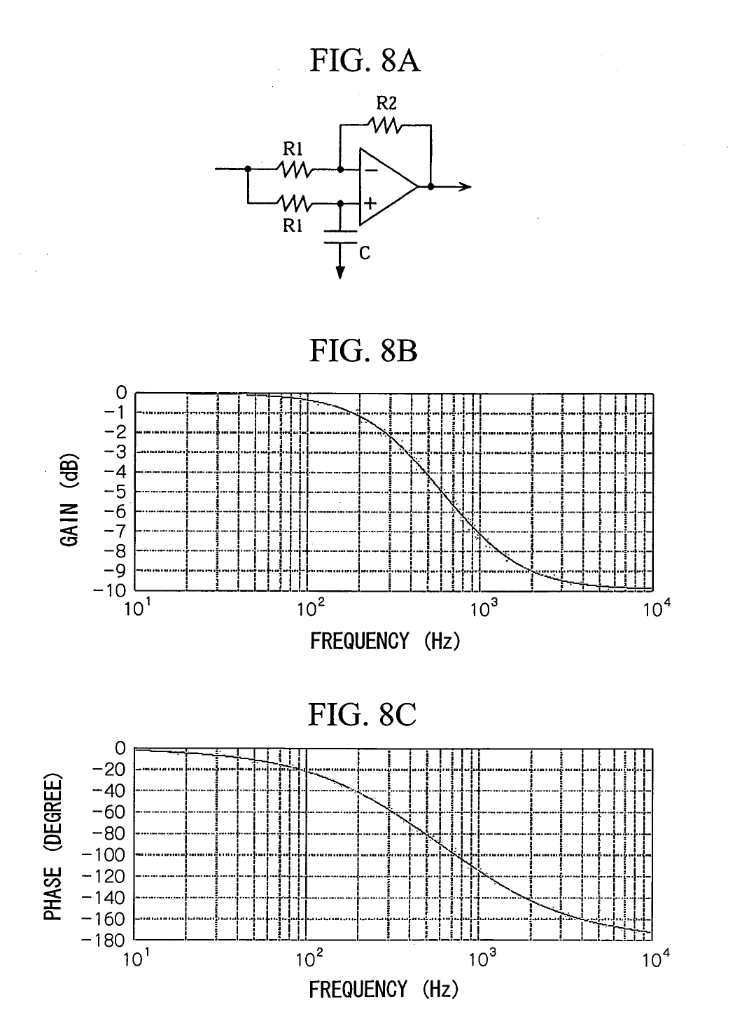

A third embodiment of this invention, in which similarly to in the second embodiment shown in FIG. 5, FIGS. 6A to 6C, and FIG. 7, the same gain is set with respect to low-frequency ranges, and weights based on the Bessel function are applied with respect to high-frequency ranges, will be described with reference to FIGS. 8A to 8C, FIGS. 9A to 9C, and FIG. 10.

In the third embodiment, a feedback resistor connected between the output terminal and inverting input terminal of the operational amplifier in the all-pass filter 3 shown in FIG. 2 is set to a value that differs from values of other resistors, thus applying desired frequency characteristics to gains. That is, a filter whose weight coefficient based on the Bessel function has a negative value is connected to a certain speaker unit as a weighting circuit, thus omitting the all-pass filter 3 that is provided in common with respect to speaker units whose weight coefficients based on the Bessel function have negative values.

FIG. 8A shows an example of the circuit constitution of the aforementioned filter.

Within the aforementioned weight coefficients C1 to C15, the weight coefficients C3 and C13 whose absolute values (i.e., 0.3621) are maximal are selected as reference coefficients, and are then normalized to “1”. For example, the weight coefficient C5=−0.1148 has an absolute value that is represented as 1/3.15(=0.1148/0.3621); hence, the gain applied to the corresponding speaker unit 1-5 is adjusted to have a difference of 20 log(1/3.15)=−9.97 dB compared with the gain of the other speaker unit 1-3.

The filter shown in FIG. 8A has a transfer function as follows:

$$H ( S ) = \frac{1 - CR 2 S}{1 - CR 1 S}$$

In the above, when circuit constants are set as C=0.1 μF, R1=4.7 kΩ, and R2=1.5 kΩ, it is possible to realize the gain characteristics shown in FIG. 8B and phase characteristics shown in FIG. 8C. That is, it is possible to provide gain characteristics having a dc gain of 0 dB and a gain of −9.97 dB in high-frequency ranges as well as phase characteristics having phase rotation of 0° in low-frequency ranges and phase rotation of 180° in high-frequency ranges.

Similarly to above, prescribed circuit constants can be determined in response to gain characteristics with respect to weight coefficients of filters connected to the other speaker units.

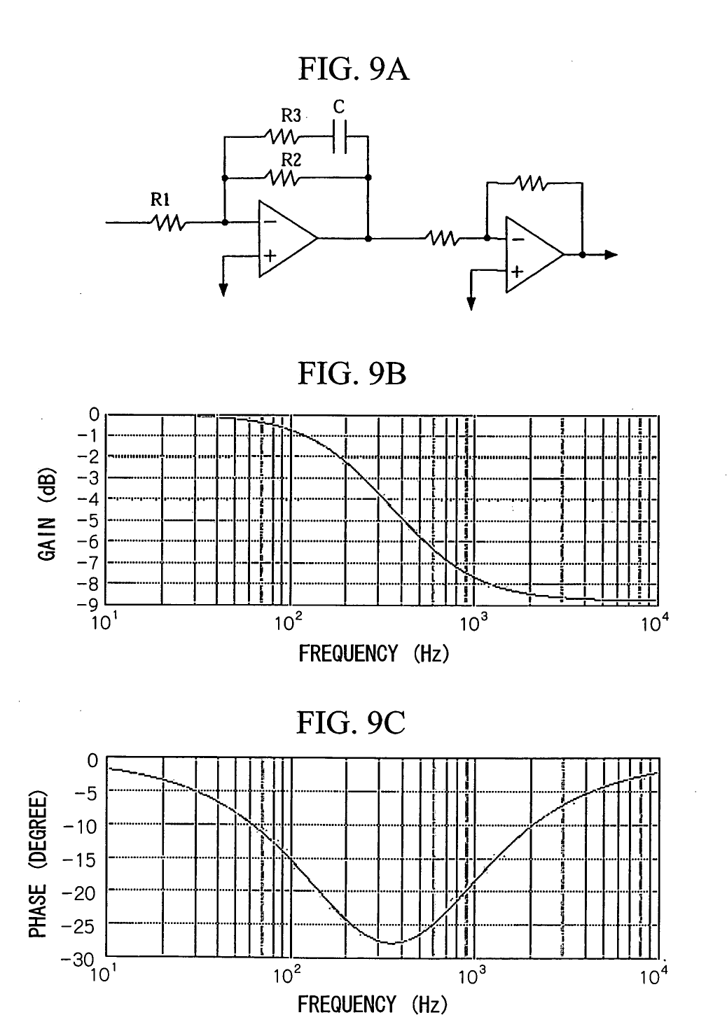

With respect to speaker units whose weight coefficients based on the Bessel function have positive values, it is possible to use filters having gain characteristics in response to ratios of the weight coefficients compared with the reference weight coefficient, and these filters can be embodied by the circuitry shown in FIG. 9A, for example.

For example, with respect to the filter corresponding to the weight coefficient C11=0.1148, the left-side circuit portion of the filter shown in FIG. 9A has a transfer function as follows:

$$H ( S ) = \frac{- 1 * R 2}{\frac{R 1 * ( 1 + CR 3 S )}{1 + ( CR 2 + CR 3 ) S}}$$

In the above, when circuit constants are set as R1=4.7 kΩ, R2=4.7 kΩ, R3=2.7 kΩ, and C−0.1 μF, it is possible to realize the gain characteristics shown in FIG. 9B and phase characteristics shown in FIG. 9C. That is, it is possible to realize gain characteristics having a dc gain of 0 dB in which the gain is reduced to −9.97 dB as the frequency becomes higher. The phase characteristics shown in FIG. 9C indicate that the phase maximally rotates by approximately 30°, and no problem occurs due to such a phase rotation over phase characteristics.

Similarly, prescribed circuit constants can be determined with respect to filters connected to the other speaker units whose weight coefficients have positive values.

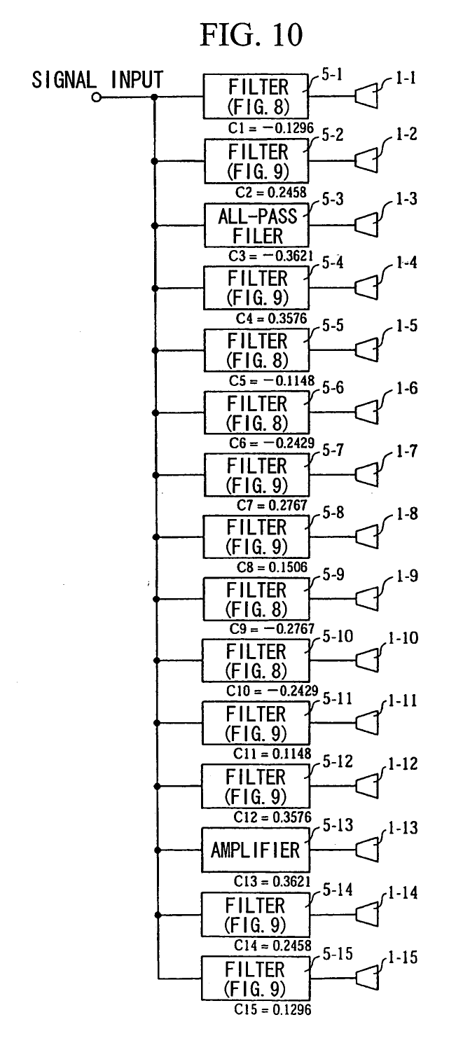

FIG. 10 is a circuit diagram showing the constitution of an array speaker system in accordance with the third embodiment of this invention, which is constituted using the filter shown in FIG. 9A instead of the filter shown in FIG. 8A. In the third embodiment, weight coefficients C3 and C13 whose absolute values are maximal within weight coefficients based on the Bessel function are selected as reference weight coefficients, and an all-pass filter 5-3 whose phase inverts in high-frequency ranges as shown in FIGS. 2A and 2B is connected to the speaker unit 1-3 whose weight coefficient has a negative value, while an amplifier 5-13 having a gain of 1 is connected to the speaker unit 1-13 whose weight coefficient has a positive value (alternatively, the amplifier 5-13 can be left out).

The filter shown in FIG. 8A having a gain in response to the ratio between the absolute value of the reference weight coefficient (i.e., 0.3621) and the absolute value of the weight coefficient applied to the corresponding speaker unit in high-frequency ranges is connected to each of the speaker units 1-1, 1-5, 1-6, 1-9, and 1-10 whose weight coefficients have negative values within the other speaker units.

In addition, the filter shown in FIG. 9A having a gain in response to the ratio between the absolute value of the reference weight coefficient and the weight coefficient applied to the corresponding speaker unit in high-frequency ranges is connected to each of the speaker units 1-2, 1-4, 1-7, 1-8, 1-11, 1-12, 1-14, and 1-15 whose weight coefficients have positive values.

As described above, in the third embodiment, the same gain having the same phase is applied to each of the speaker units with respect to low-frequency ranges having no problem regarding beams and comb shapes in audio emission characteristics, while weight coefficients based on the Bessel function are applied to each of them with respect to high-frequency ranges. Therefore, it is possible to avoid a degradation of audio emission characteristics in low-frequency sound; and it is possible to avoid the occurrence of beams and comb shapes in audio emission characteristics. Furthermore, it is possible to omit the all-pass filter, which is connected in common to all speaker units.

The aforementioned embodiment is described and embodied using analog filters, but it can be embodied using a digital filter shown in FIG. 4A realizing SZ transform (e.g., bilinear transform). In addition, it is possible to arbitrarily select the reference speaker unit.

Next, a center frequency (i.e., a frequency causing phase rotation of 90°) in the phase rotation of the aforementioned all-pass filter and the filter shown in FIG. 8A will be described.

For example, in the aforementioned simulation, fifteen speaker units are disposed with the distance d (=2.5 cm) therebetween, wherein the overall width of the speaker unit string is 35 cm (=2.5 cm×14). Simulation is performed in consideration of the speed of sound, i.e., 340 m/sec, so that the frequency having a single wavelength corresponding to the width of the speaker unit string, i.e., 35 cm, is 34000/35=971 Hz.

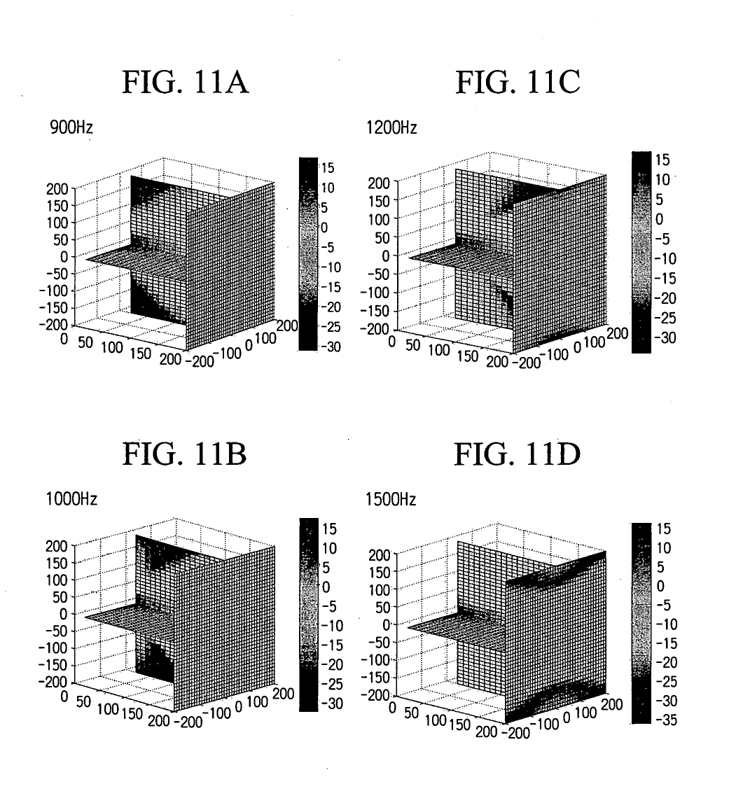

FIGS. 11A to 11D show simulation results that are produced when all the fifteen speaker units have the same weight of 1. Herein, FIGS. 11A, 11B, 11C, and 11D show audio emission characteristics in response to audio frequencies of 900 Hz, 1000 Hz, 1200 Hz, and 1500 Hz respectively.

FIGS. 11A to 11D show that sound beams may apparently emerge in frequencies higher than the prescribed frequency (approximately, 1000 Hz) substantially corresponding to the wavelength having the width of the speaker unit string. For this reason, the center frequency (i.e., the frequency causing phase rotation of 90°) in the phase rotation of the all-pass filter or the filter shown in FIG. 8A is set in conformity with the wavelength having the width of the speaker unit string, so that weighting effects due to weight coefficients based on the Bessel function may start to work in frequencies higher than the center frequency; thus, it is expected to produce an improved result with regard to audio emission characteristics.

As described above, it is preferable that the center frequency (corresponding to phase rotation of 90°) in the phase rotation of the all-pass filter be set in proximity to the frequency corresponding to the wavelength of the speaker unit string of the array speaker system.

The aforementioned embodiment is constituted using the all-pass filter (or the filter shown in FIG. 8A), which is formed in an analog or digital manner, whereas this invention can be embodied using other measures.

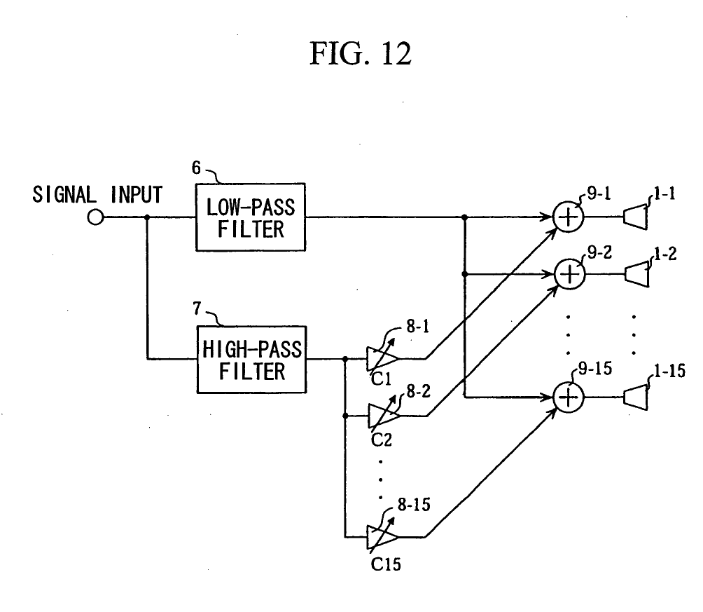

FIG. 12 shows essential parts of the circuit configuration of an array speaker system in accordance with a fourth embodiment of this invention, which is constituted without using the aforementioned all-pass filter.

Reference numerals 1-1 to 1-15 designate speaker units similar to the foregoing ones; reference numeral 6 designates a low-pass filter for filtering signal components of low-frequency ranges from input signals; reference numeral 7 designates a high-pass filter for filtering signal components of high-frequency ranges from input signals; reference numerals 8-1 to 8-15 designate weighting means for imparting weights using weight coefficients C1 to C15 based on the Bessel function to signal components of high-frequency ranges supplied from the high-pass filter 7; and reference numerals 9-1 to 9-15 designate adders, which are arranged in correspondence with the speaker units 1-1 to 1-15 respectively and which add signal components of low-frequency ranges (to which a gain of 1 is applied) provided from the low-pass filter 6 and signal components of high-frequency ranges, to which the weighting means 8-1 to 8-15 impart weights based on the Bessel function, together, thus supplying addition results to the speaker units 1-1 to 1-15 respectively. Herein, the same cutoff frequency is set for the low-pass filter 6 and the high-pass filter 7, for example; hence, input signals are divided into signal components of low-frequency ranges and signal components of high-frequency ranges. Incidentally, the low-pass filter 6 and the high-pass filter 7 can be each constituted using an analog filter or a digital filter.

In the aforementioned fourth embodiment, input signals are divided into signal components of low-frequency ranges and signal components of high-frequency ranges by use of the frequency corresponding to the wavelength identical to the width of the speaker unit string; the corresponding speaker units are subjected to weighting using a gain of 1 with respect to signal components of low-frequency ranges; they are subjected to weighting using weight coefficients based on the Bessel function with respect to signal components of high-frequency ranges; and thereafter, these signals components are added together and output. Thus, similarly to in the foregoing embodiments using the all-pass filters, it is possible to secure a sufficiently high gain in low-frequency ranges, and it is possible to avoid the occurrence of beams and comb shapes in audio emission characteristics with respect to high-frequency ranges.

The aforementioned embodiments are each constituted using fifteen speaker units; however, this invention effectively works in any array speaker system having five speaker units or more. In addition, weight coefficients based on the Bessel function are not necessarily limited to the aforementioned values.

As described heretofore, in the array speaker system of this invention, speaker units are each driven with positive phases with respect to low-frequency ranges; hence, it is possible to prevent audio emission characteristics from deteriorating irrespective of inverse phase components, which occur due to negative values of weight coefficients based on the Bessel function; and with respect to high-frequency ranges, speaker units are each driven with weighting using weight coefficients based on the Bessel function; hence, it is possible to avoid the occurrence of beams and comb shapes in sound. Therefore, it is possible to avoid the occurrence of beams and comb shapes in audio emission characteristics in a broad range of frequencies ranging from low-frequency ranges to high-frequency ranges, and it is possible to realize efficient audio emission in which a sound field is formed in a spherical manner.

Incidentally, this invention is not necessarily limited to the aforementioned embodiments; hence, it may embrace design changes within the scope of the invention.

1. An array speaker system that is constituted by arraying a plurality of speaker units, wherein all the speaker units are driven with a same phase with respect to low-frequency signals, and the speaker units are each driven with weight coefficients based on a Bessel function with respect to high-frequency signals.

2. An array speaker system that is constituted by arraying a plurality of speaker units, wherein all the speaker units are driven with a same phase and with a same gain with respect to low-frequency signals, and the speaker units are each driven with weight coefficients based on a Bessel function with respect to high-frequency signals.

3. An array speaker system that is constituted by array a plurality of speaker units, said array speaker system comprising an all-pass filter whose phase is subjected to rotation by 180° in high-frequency ranges, wherein ones of the speaker units whose weight coefficients based on a Bessel function have negative values are each driven with weights corresponding to absolute values of the weight coefficients, which are imparted to a signal transmitted through the all-pass filter, and wherein ones of the speaker units whose weight coefficients based on the Bessel function do not have negative values are each driven with the weight coefficients thereof.

4. An array speaker system that is constituted by arraying a plurality of speaker units, said array speaker system comprising:
an all-pass filter whose phase is subjected to rotation by 180° in high-frequency ranges;
a means that is provided in connection with each of ones of the speaker units whose weight coefficients based on a Bessel function have negative values and that inputs a signal transmitted through the all-pass filter so as to impart gain characteristics, corresponding to absolute values of the weight coefficients, to signal components of high-frequency ranges; and
a means that is provided in connection with each of ones of the speaker units whose weight coefficients based on the Bessel function do not have negative values and that imparts gain characteristics, corresponding to the weight coefficients thereof, to signal components of high-frequency ranges.

5. An array speaker system according to claim 3, wherein the all-pass filter has a phase rotation that is set to 90° with respect to frequencies in proximity to a frequency matching a wavelength corresponding to a width of each speaker unit within an array of the speaker units.

6. (canceled)

7. An array speaker system that is constituted by arraying a plurality of speaker units, said array speaker system comprising:
a filter means for dividing an input signal into signal components of low-frequency ranges and signal components of high-frequency ranges;
a weighting means that is provided in connection with each of the speaker units and that imparts weight coefficients based on a Bessel function to the signal components of the high-frequency ranges, which are divided by the filter means; and
an addition means that is provided in connection with each of the speaker units and that adds the signal components of the low-frequency ranges, which are divided by the filter means, to the signal components of the high-frequency ranges, to which the weighting means imparts the weight coefficients based on the Bessel function, thus outputting addition results to the corresponding speaker units.

8. An array speaker system according to any one of claims 1 to 5 and 7, wherein the plurality of speaker units are installed in a common enclosure.

9. An array speaker system according to any one of claims 1 to 5 and 7, wherein the plurality of speaker units are installed in a common enclosure of a bass-reflex type.

10. A driving method for an array speaker system that is constituted by arraying a plurality of speaker units, said driving method for an array speaker system comprising the steps of:
driving all the speaker units with a same phase with respect to low-frequency signals; and
driving the speaker units separately with weight coefficients based on Bessel function with respect to high-frequency signals.

11. A driving method for an array speaker system that is constituted by arraying a plurality of speaker units, said driving method for an array speaker system comprising the steps of:
driving all the speaker units with a same phase and with a same gain with respect to low-frequency signals; and
driving the speaker units separately with weight coefficients based on a Bessel function with respect to high-frequency signals.

12. A driving method for an array speaker system that is constituted by arraying a plurality of speaker units and that includes an all-pass filter whose phase is subjected to rotation by 180° in high-frequency ranges, said driving method for an array speaker system comprising the steps of:
driving ones of the speaker units whose weight coefficients based on a Bessel function have negative values with weights corresponding to absolute values of the weight coefficients, which are imparted to a signal transmitted through the all-pass filter; and
driving ones of the speaker units whose weight coefficients based on the Bessel function do not have negative values with the weight coefficients thereof.

13. A driving method for an array speaker system that is constituted by arraying a plurality of speaker units and that includes an all-pass filter whose phase is subjected to rotation by 180° in high-frequency ranges, said driving method for an array speaker system comprising the steps of:
inputting a signal transmitted through the all-pass filter so as to impart gain characteristics, corresponding to absolute values of weight coefficients, to signal components of high-frequency ranges with respect to ones of the speaker units whose weight coefficients based on a Bessel function have negative values; and
imparting gain characteristics, corresponding to the weight coefficients, to the signals of the high-frequency ranges with respect to ones of the speaker units whose weight coefficients based on the Bessel function do not have negative values.

14. The driving method for an array speaker system according to claim 13, wherein the all-pass filter has a phase rotation that is set to 90° in frequencies in proximity to a frequency matching a wavelength corresponding to a width of each speaker unit within an array of the speaker units.

15. (canceled)

16. A driving method for an array speaker system that is constituted by arraying a plurality of speaker units, said driving method for an array speaker unit comprising the steps of:
dividing an input signal into signal components of low-frequency ranges and signal components of high-frequency ranges;
imparting weight coefficients based on a Bessel function to the signal components of the divided high-frequency ranges with respect to the speaker units respectively; and
adding the signal components of the divided low-frequency ranges to the signal components of the high-frequency ranges, to which the weight coefficients based on the Bessel function are imparted, thus outputting addition results to the speaker units respectively.
